(19) United States
(12) Patent Application Publication
(10) Pub. No.: US 2022/0264758 A1
(43) Pub. Date: Aug. 18, 2022

(54) ELECTRONIC DEVICE SUPPORT CAPABLE OF GROUNDING

(71) Applicant: CINCOZE CO., LTD., New Taipei City (TW)

(72) Inventor: HSIN-TE CHIEN, New Taipei City (TW)

(21) Appl. No.: 17/320,225

(22) Filed: May 14, 2021

(30) Foreign Application Priority Data
Feb. 17, 2021 (TW) 110105292

(51) Int. Cl. H05K 7/02

(52) U.S. Cl. CPC H05K 7/02

(57) ABSTRACT

An electronic device support capable of grounding is disclosed. The electronic device support is adapted to fix an electronic device in place. The electronic device includes a panel and a support grounding element. The panel is for use in fixing a rear side of the electronic device in place. The support grounding element is disposed on the panel.

### CROSS-REFERENCE TO RELATED APPLICATION

This non-provisional application claims priority under 35 U.S.C. § 119(a) on Patent Application No(s). 110105292 filed in Taiwan, R.O.C. on Feb. 17, 2021, the entire contents of which are hereby incorporated by reference.

### BACKGROUND OF THE INVENTION

### 1. Field of the Invention

The present disclosure relates to electronic device supports, and in particular to an electronic device support capable of grounding.

### 2. Description of the Related Art

A computer host of a conventional industrial computer typically comes with a grounding element. The grounding element removes unnecessary electrical charges from the computer host to prevent the computer host from developing short circuits. To save space, some industrial computers are wall-mounted, i.e., mounted on walls. To this end, the grounding element is disposed on the front side of the computer host. However, the untidy appearance of the computer host is exacerbated by a grounding wire which connects to the grounding element and then connects to a wall. Furthermore, electrical connection portions are disposed on the front side of the computer host, and the grounding element is likely to electrically interfere with the electrical connection portions.

### BRIEF SUMMARY OF THE INVENTION

An objective of the present disclosure is to provide an electronic device support capable of grounding to not only maintain the neatness of the appearance of an electronic device supported by the electronic device support but also reduce the electrical interference otherwise caused to the electrical connection portions of the electronic device.

To achieve at least the above objective, the present disclosure provides in an aspect thereof an electronic device support capable of grounding. The electronic device support is adapted for use in fixing an electronic device in place. The electronic device support comprises a panel and a support grounding element. The panel is for use in fixing a rear side of the electronic device in place. The support grounding element is disposed on the panel.

In an embodiment, the panel has a fixation area for use in fixing the rear side of the electronic device in place, and the support grounding element is located outside the fixation area.

In an embodiment, the support grounding element is positioned proximate to a bottom end of the panel.

In an embodiment, the panel is a metallic panel, and the electronic device has a metallic casing, wherein the support grounding element is a metallic element.

In an embodiment, the electronic device further has a front side opposing the rear side, and a computer host grounding element is disposed on the front side.

In an embodiment, the support grounding element is a protruding rod connected to the panel.

Owing to the support grounding element, the electronic device support capable of grounding has advantages as follows: no grounding elements need to be disposed on the front side of the electronic device, such that not only does the electronic device have a neat appearance, but the electrical connection portions of the electronic device are also free of electrical interference.

### BRIEF DESCRIPTION OF THE DRAWINGS

FIG. 1 is a schematic view of an electronic device support capable of grounding according to a preferred embodiment of the present disclosure.

FIG. 2 is an exploded view of the electronic device support capable of grounding and an electronic device according to a preferred embodiment of the present disclosure.

FIG. 3 is a cutaway view of the electronic device support capable of grounding and the electronic device according to a preferred embodiment of the present disclosure.

### DETAILED DESCRIPTION OF THE INVENTION

To facilitate understanding of the object, characteristics and effects of this present disclosure, embodiments together with the attached drawings for the detailed description of the present disclosure are provided.

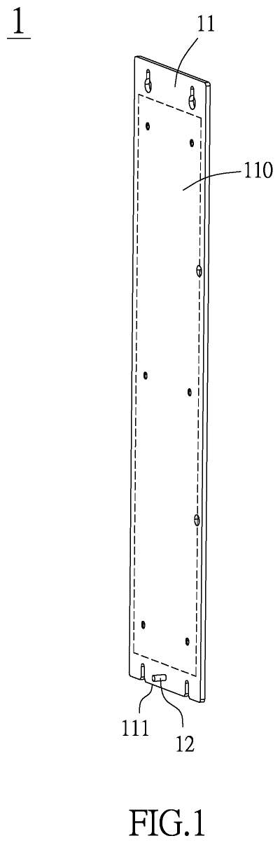

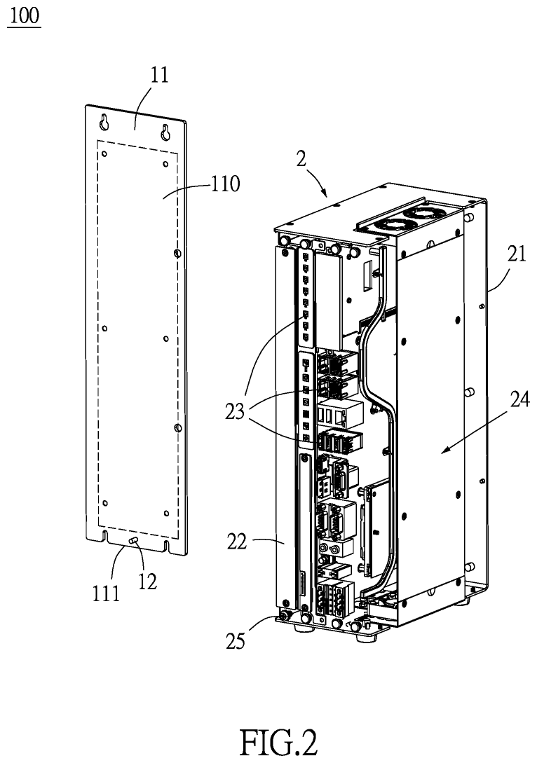

Referring to FIG. 1 and FIG. 2, the present disclosure provides in an aspect thereof an electronic device support 1 capable of grounding. The electronic device support 1 is adapted for use in fixing an electronic device 2 in place and comprises a panel 11 and a support grounding element 12. The panel 11 is for use in fixing a rear side 21 of the electronic device 2 in place. The support grounding element 12 is disposed on the panel 11. The electronic device 2 is an industrial computer, but the present disclosure is not limited thereto. The electronic device support 1 supports the electronic device 2 and is either mounted on a wall or lies on a horizontal surface.

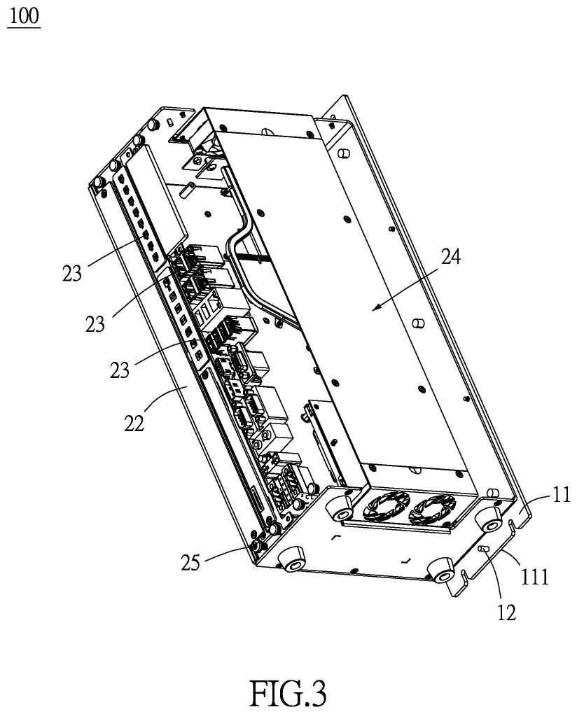

Referring to FIG. 2 and FIG. 3, the electronic device support 1 and the electronic device 2 together form an electronic device assembly 100. The electronic device 2 has a front side 22 opposing the rear side 21. A plurality of electrical connection portions 23 are disposed on the front side 22.

Owing to the support grounding element 12, the electronic device support 1 capable of grounding has advantages as follows: no grounding elements need to be disposed on the front side 22 of the electronic device 2, such that not only does the electronic device 2 have a neat appearance, but the electrical connection portions 23 of the electronic device 2 are also free of electrical interference.

Referring to FIG. 1 through FIG. 3, in an embodiment, the panel 11 has a fixation area 110 for use in fixing the rear side 21 of the electronic device 2 in place, and the support grounding element 12 is located outside the fixation area 110. The panel 11 has a slightly greater area than the rear side 21 of the electronic device 2; thus, the panel 11 protrudes from the rear side 21 and thereby can accommodate the support grounding element 12 easily. The support grounding element 12 is positioned proximate to a bottom end 111 of the panel 11, but the present disclosure is not limited thereto. The support grounding element 12 is disposed on the panel 11 and may be located at any position which the electronic device 2 is not fixed to.

Referring to FIG. 1 and FIG. 2, in an embodiment, when the electronic device support 1 is wall-mounted, the panel 11 is fixed to a wall (not shown) with a plurality of fixation elements (not shown), for example, screws.

Referring to FIG. 2 and FIG. 3, in an embodiment, the panel 11 is a metallic panel, and the electronic device 2 has a metallic casing 24. The support grounding element 12 is a metallic element, for example, a protruding rod connected to the panel 11. Consequently, the support grounding element 12 connects a grounding wire (not shown) to the wall or floor, thereby effectively removing electrical charges otherwise accumulated in the electronic device 2.

Referring to FIG. 2 and FIG. 3, in an embodiment, a computer host grounding element 25 is disposed at a corner on the front side 22 of the electronic device 2. In the presence of the support grounding element 12, the computer host grounding element 25 need not connect to a grounding wire; thus, not only is the appearance of the electronic device 2 neat, but electrical interference with the electrical connection portions 23 is also precluded. However, in some situations, for example, when the electronic device 2 is not fixed to a wall but has to be rested on a desk or a platform, both the computer host grounding element 25 and the support grounding element 12 may be connected to the grounding wire to ground the electronic device 2 better. The computer host grounding element 25 is a metallic bolt, but the present disclosure is not limited thereto.

Referring to FIG. 1 through FIG. 3, in an embodiment, the electronic device 2 is fastened to the panel 11 with a plurality of screws (not shown), but the present disclosure is not limited thereto.

While the present disclosure has been described by means of specific embodiments, numerous modifications and variations could be made thereto by those skilled in the art without departing from the scope and spirit of the present disclosure set forth in the claims.

What is claimed is:

1. An electronic device support capable of grounding, adapted to fix an electronic device in place, the electronic device support comprising:
a panel for fixing a rear side of the electronic device in place; and
a support grounding element disposed on the panel.

2. The electronic device support capable of grounding according to claim 1, wherein the panel has a fixation area for use in fixing the rear side of the electronic device in place, and the support grounding element is located outside the fixation area.

3. The electronic device support capable of grounding according to claim 1, wherein the support grounding element is positioned proximate to a bottom end of the panel.

4. The electronic device support capable of grounding according to claim 1, wherein the panel is a metallic panel, and the electronic device has a metallic casing, with the support grounding element being a metallic element.

5. The electronic device support capable of grounding according to claim 1, wherein the support grounding element is a protruding rod connected to the panel.

6. The electronic device support capable of grounding according to claim 1, wherein the electronic device further has a front side opposing the rear side, and a computer host grounding element is disposed on the front side.
